(19) United States
(12) Patent Application Publication
(10) Pub. No.: US 2012/0024562 A1
(43) Pub. Date: Feb. 2, 2012

(54) Electical Panel for a Desktop Vacuum Chamber Assembly

(76) Inventor: Andrew E. Kalman, San Francisco, CA (US)

(21) Appl. No.: 13/019,527

(22) Filed: Feb. 2, 2011

Related U.S. Application Data
(60) Provisional application No. 61/368,915, filed on Jul. 29, 2010.

(51) Int. Cl. H05K 5/06

(52) U.S. Cl. 174/50.5

(57) ABSTRACT

A method for establishing a communication path between connectors on opposite sides of a PCB mounted to a vacuum chamber with an O-ring seal includes the steps (a) providing a plurality of vias through the PCB in the form of a connector pin pattern within the O-ring seal area to enable surface mounting of the type connector to the vacuum side of the PCB, (b) providing a plurality of vias through the PCB in the form of a pin pattern compatible to the pin pattern of step (a) outside of the O-ring seal area to enable plug in of the type connector to the pin pattern on the non-vacuum side of the PCB, and (c) on the non-vacuum side of the PCB, providing a conductive trace leading from each of the exposed vias of step (a) across the face of the PCB to each of the exposed vias of step (b).

### CROSS-REFERENCE TO RELATED DOCUMENTS

The present application claims priority to provisional application Ser. No. 61/368,915, filed on Jul. 29, 2010. The application above is incorporated in its entirety herein by reference.

### BACKGROUND OF THE INVENTION

1. Field of the Invention

The present invention is in the field of vacuum equipment including vacuum chambers and pertains particularly to methods and apparatus for conducting processes under vacuum utilizing a vacuum chamber and maintaining vacuum with minimal vacuum seals.

2. Discussion of the State of the Art

Vacuum chambers are utilized for a variety of manufacturing, test and research activities. The construction of a vacuum chamber varies based in part on the range of vacuum the chamber is designed to produce and maintain. Such chambers (belled or domed covers) are often made of Aluminum or Stainless Steel. Careful attention is paid to the materials used because of difficulties involved in achieving ultra or better vacuums (1×10−7 Torr or better) due in large part to contamination, out-gassing, implosion, and so on.

Typical approaches to vacuum chamber design require the use of expensive components to achieve prescribed vacuum levels. External components include vacuum pumps, gauges, valves, and the like. O-rings of various materials, and other seals such as those made from malleable copper, are commonly used when joining two components of a vacuum chamber assembly together. The inventors are aware of a CubeSat Testing Equipment Chamber (CTEC) that utilizes a non-monolithic base made from Ultra-high Molecular Weight Polyethylene (UHMW PE). The cover or dome is in the form of a bell jar. Fittings are generally screwed into the sides of the UHMW PE ring. Use of a glass bell jar as a cover is interesting as it allows in-situ observation of the device(s) under test, and it is transparent to RF energy.

Moreover, vacuum chamber assemblies are sometimes assembled from multiple components, each retaining a seal for maintaining integrity of the vacuum. Each part combined to create a chamber assembly introduces a potential for vacuum leakage and contamination. One problem relates to electrical and signal pass-through from vacuum to atmosphere during vacuum processing. Hermetic connectors are expensive and cannot be used in the general-purpose sense. Therefore, what is clearly needed is an electrical pass-through panel for a vacuum chamber assembly that allows standard non-hermetic electrical connectors to be used in place of specially sealed glass connectors and the like.

### SUMMARY OF THE INVENTION

The problem stated above is that the ability to provide efficient electrical/signal pass-through between vacuum and atmosphere is desirable for a vacuum process that utilizes a vacuum processing chamber, but many of the conventional means for passing data from vacuum to atmosphere, such as hermetically sealed and static connectors also creates higher cost in initial set-up and in maintenance. The inventors therefore considered functional components of a vacuum processing system, looking for elements that exhibit interoperability that could potentially be harnessed to provide electrical/signal pass-through in vacuum processing but in a manner that would not create undue expense or extra work.

Every vacuum process is driven by the integrity of a vacuum chamber, one by-product of which is minimal vacuum leakage, out-gassing, and contaminants in the end products. Most such processing systems employ vacuum chamber assemblies, vacuum pumps, and vacuum gauges, to create and maintain the vacuum environments, and vacuum chamber electrical pass-through ports are typically a part of such apparatus.

The present inventor realized in an inventive moment that if, during vacuum processing, standard connectors could be implemented both on the vacuum and non-vacuum sides of a chamber, significant reduction is set-up and cost might result. The inventor therefore constructed a unique electrical pass-through panel for vacuum processing that allowed utilization of standard non-hermetic electrical connectors on both sides of the chamber in a variety of different processing environments while employing minimal seals to achieve and maintain the vacuum states required. A significant improvement in process efficiency and cost reduction results, with no impediment to overall processing time or requirements.

Accordingly, in an embodiment of the present invention, an electrical pass-through panel for a vacuum chamber is provided and includes a printed circuit board (PCB) having a substrate, at least one conductive and non-conductive material layer, the PCB sealed in mounting to the vacuum chamber with an O-ring seal seated in a groove provided about an opening through the wall of the vacuum chamber, a plurality of vias provided through the PCB within the O-ring seal area, the vias corresponding directly to pin patterns for specified standard electrical connectors mountable on the vacuum side of the PCB, and a plurality of conductive traces defined on the non-vacuum side of the PCB, the traces in communication with the vias, the traces extending outside the O-ring seal area and culminating at a like number of vias arranged in like pin patterns for standard electrical connectors mountable on the non-vacuum side of the PCB outside of the area bounded by the O-ring seal.

High speed data signals are passed through the vias and traces from the vacuum-side connectors plugged into the PCB within the O-ring seal area to the non-vacuum-side connectors plugged into the PCB outside of the O-ring seal area while the chamber is under vacuum.

In one embodiment, the standard connectors include but are not limited to universal serial bus (USB), 10baseT, insulation displacement connectors (IDC), and terminal blocks. In a preferred embodiment, the vias are electroplated. In a preferred embodiment, the conductive layer is a copper layer. In this embodiment, the conductive traces are copper traces. In one embodiment, the vias are sealed on the outside surface of the PCB with a vacuum compatible sealant. In one embodiment, the vias are filled with solder.

In a preferred embodiment, the electrical pass-through panel is a modular assembly that can be dismounted and remounted at another opening in the vacuum chamber. In one embodiment, the electrical pass-through panel further includes a horizontally disposed PCB panel connected thereto by headers, the horizontal panel supported by standoffs. In one embodiment, the vacuum-side connectors are surface mounted and the non-vacuum side connectors are general-purpose connectors.

According to one aspect of the present invention, a method for establishing a communication path between standard connectors on opposite sides of a PCB mounted to a vacuum chamber with an O-ring seal. The method includes the steps (a) providing a plurality of vias through the PCB in the form of a connector pin pattern within the O-ring seal area to enable surface mounting of the type connector to the vacuum side of the PCB, (b) providing a plurality of vias through the PCB in the form of a pin pattern compatible to the pin pattern of step (a) outside of the O-ring seal area to enable plug in of the type connector to the pin pattern on the non-vacuum side of the PCB, and (c) on the non-vacuum side of the PCB, providing a conductive trace leading from each of the exposed vias of step (a) across the face of the PCB to each of the exposed vias of step (b).

In one aspect of the method, in step (a), the type connector is one of a universal serial bus (USB), 10baseT, insulation displacement connector (IDC), or a terminal block. In one aspect, in steps (a) and (b), the vias are electroplated and filled with solder. In one aspect in step (b), the vias are sealed with a vacuum compatible sealant. In a preferred aspect, in step (c), the conductive traces are copper traces. In a preferred aspect, in step (c), the conductive traces are controlled with respect to impedance relative to the type connector subject to the communication path.

### BRIEF DESCRIPTION OF THE DRAWING FIGURES

FIG. 1 is a perspective view of a desktop vacuum chamber assembly according to an embodiment of the present invention.

FIG. 2 is a perspective view of the desktop vacuum chamber assembly of FIG. 1 extended in length by adding a module extender section according to an embodiment of the present invention.

FIG. 3 is a partial view of a chamber base with an electrical pass-through panel and component shelf installed according to an embodiment of the present invention.

FIG. 4 is an elevation view of the vacuum side of the electrical pass-through panel of FIG. 3.

FIG. 5 is an elevation view of the atmospheric side of the electrical pass-through panel of FIG. 3.

FIG. 6 is a process flow chart illustrating steps for mounting a chamber assembly to an optical table.

### DETAILED DESCRIPTION OF THE INVENTION

The inventors provide a unique vacuum chamber assembly that has a monolithic base requiring only one sealing point to adequately maintain vacuum. Other novel features relative to the present invention will also be detailed in descriptions of various embodiments in the specification following. The present invention will be described in enabling detail using the following examples, which may describe more than one relevant embodiment falling within the scope of the present invention.

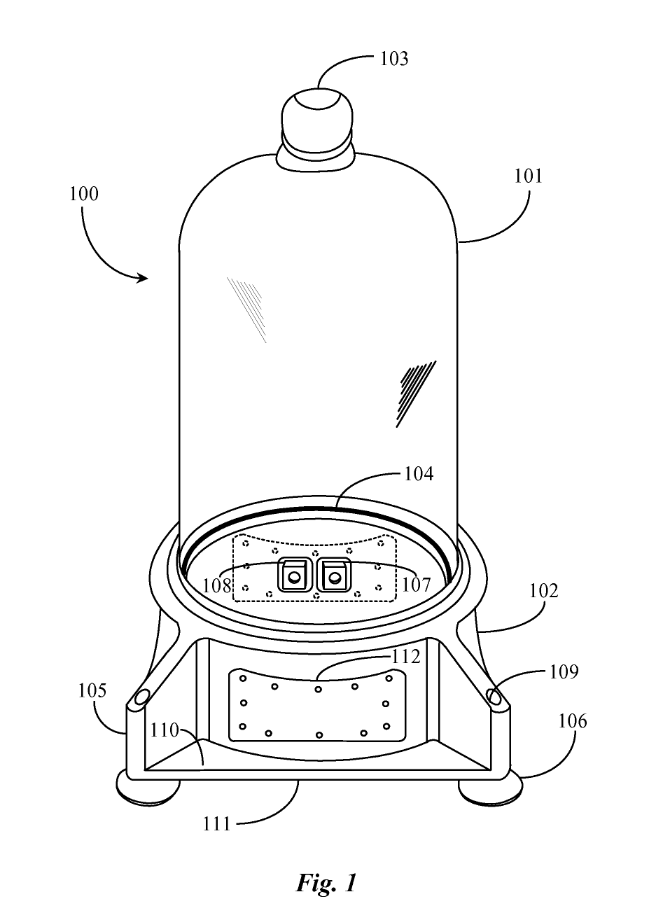

FIG. 1 is a perspective view of a desktop vacuum chamber assembly 100 according to an embodiment of the present invention. Chamber 100 is characterized as an assembly that includes a base section 102 and a domed section or bell 101. Base 102 is substantially hollow on the inside and includes a closed bottom wall and open top. Base 102 is monolithic in design meaning that it is manufactured from a single material in contiguous fashion, and therefore can be made of any material type. In one embodiment, base 102 is machined from aluminum or stainless steel. In one embodiment, the base material is machined from Ultra-high Molecular Weight Polyethylene (UHMW PE). In alternative embodiments the base may be molded from any one of various suitable materials.

Base 102 is somewhat annular in profile and includes at least three protruding fins 105 in the embodiment illustrated in FIG. 1. Fins 105 are symmetrically located about the base body and are structurally supported by a shelf having a top surface 110 and bottom surface 111. Fins 105 provide mounting locations for mounting base 102 to an optical plate (not illustrated). In one embodiment base 102 has another geometric profile such as elliptical, or rectangular. Different body profiles are possible without departing from the spirit and scope of the present invention.

In a variation of the embodiment described immediately above, isolator feet 106 are provided (one per fin) for the purpose of forming a tabletop stand for base 102. In this example two fins 105 are visible. It may be assumed that at least three fins 105 are provided. Isolator feet may be manufactured of a metal such as aluminum or steel, or of a plastic or other durable material. Each fin 105 of base 102 includes a vertically placed counter-bored opening 109 that extends completely through the fin from the top surface of each fin through a bottom surface 111. Isolator feet 106 include threaded openings adapted to accept a bolt inserted through the top of bore 109 through a special washer (not illustrated) seated within the counter bore of each opening 109. When base 102 is mounted to an optical plate or other suitable surface or device, the isolator feet are removed and the appropriate bolts are swapped out for mounting the base to an optical plate or other surface.

In this example, bell 101 is a glass bell jar. A glass bell jar may be manufactured of Pyrex or quartz glass. In one embodiment bell 101 is made of aluminum or stainless steel. The exact material, shape, and wall thickness of bell 101 may depend at least in part on the type of vacuum pressure the bell will be subjected to during specific types of processing under vacuum. Bell 101 may include a flange that is sealed against an O-ring seal 104 that is seated in a groove provided for the purpose in the base section 102. In one embodiment bell 101 is not flanged at all on the open end, rather the wall thickness is such that the ground and polished end of the jar seats against the O-ring. In any case only one main seal need be provided to maintain vacuum integrity.

Bell 101 includes a ball joint 103 provided for lifting the dome off of base 102 and lowering the dome onto base 102. Ball joint 103 may be adapted to be fitted to gas source using typical ball-joint and cup fitting for attaching a hose to the top of bell 101 for interjecting a gas or a chemical species into the chamber during processing under vacuum. In one embodiment bell 101 is completely closed and has no ball joint, handle, or any other apparatus attached to the top. In other embodiments bell 101 has a ball-joint or other fitting through which a gas source may be attached for injecting gas or chemical species into the vacuum process.

Base 102 includes at least one access port panel 112 mounted over one or more openings provided through the sidewall. Access port panel 112 may be manufactured of aluminum, stainless steel, or other durable material that can withstand vacuum pressure. Panel 112 provides modular access to the internals of the chamber assembly during vacuum processing. Panel 112 is featureless in this example and therefore is considered a modular access port cover that is screwed or bolted onto the wall of base 102 over some opening provided for one or more optional port fittings. As a cover, panel 112 can be swapped for any definitive type of access port panel that has the features for integrating the portages through the chamber assembly wall. Panel 112 may be about one-eighth of an inch thick and has 12 mounting holes in this example. A vacuum seal (not illustrated) provides vacuum integrity behind the cover. The vacuum seal may be an O-ring seal in one embodiment.

Port panel 112 may include port covers, which are mounted on the chamber base wall where there will be no access through that part of the assembly. Port panels also include the panels having specific features to enable pass-through of gasses, fluids, electrical data, vacuum and purge lines, and so on. The modular architecture common to both access port panels and the featureless port covers comprises the mounting hole or bolt pattern, the sealing apparatus feature (typically O-ring seal) and the overall shape and dimensions of the panel. Opposite cover 112 on base section 102, there is an access port panel mounted onto the base wall (broken boundary) that includes openings for NPT fittings 107 and 108 (one for vacuum and one for fluid). In this embodiment, a chamber assembly with panels and or covers installed would require one seal for each interface.

In this example, the architecture of base 102 includes fins 105 that are connected by web material or webbed sections marked by (surfaces 110, 111) that strengthen the vertical mounting points and add structural integrity to the body of the base section under extreme vacuum pressures. It is important to note herein that other shapes and architectures may be observed without departing from the spirit and scope of the present invention.

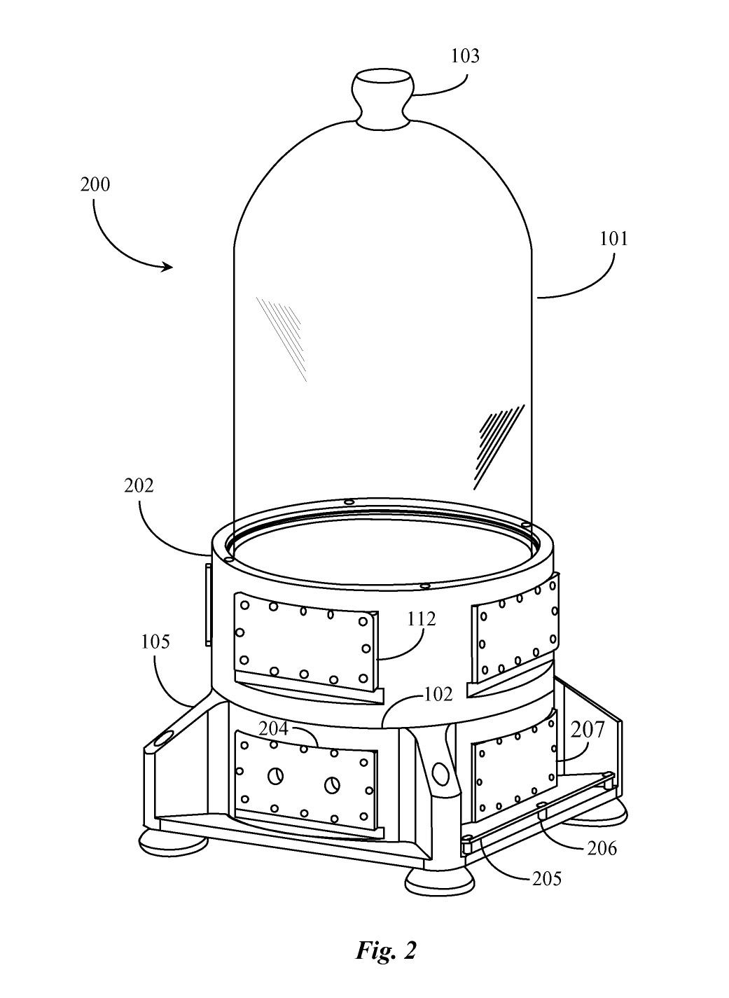

FIG. 2 is a perspective view of the desktop vacuum chamber assembly of FIG. 1 extended in length by adding a module extender section 202 according to an embodiment of the present invention. A vacuum chamber assembly 200 includes base 102 with mounting fins 105 and bell 101 with ball joint 103. The chamber assembly further includes base extender section 202. Extender section 202 may be manufactured from aluminum, stainless steel, UHMV PE, or some other material suitable for vacuum process chambers. In a preferred aspect, the extender section is manufactured from the same material as the base section.

Extender 202 is adapted to seat within or against base section 102 and is sealed by O-ring. The top opening of extender section 202 is adapted to accept bell 101 against an O-ring seal. Therefore the assembly requires one additional O-ring seal for every extender section added. In one embodiment the topside of a base extender might be larger in diameter than the bottom end enabling use of a wider bell. In other embodiments, the top end of an extender is of a differing geometric shape than the bottom end allowing installation of a bell having a differing geometry than the original bell adapted to seat against the base section of the assembly. For example, a base section may be round and the topside of the extender section might be elliptical enabling use of an elliptical bell jar instead of a round bell jar, for example.

In this example, base section 102 has four mounting fins 105. Base section 102 has an access port panel 204 adapted for vacuum and fluid pass through. Base section 102 also includes an electrical pass through panel 207 that has the same modular architecture for mounting as cover panels 104 or any of the variety of access port panels that might be provided for any particular vacuum process. Electrical pass through panel 207 can be connected to a horizontally disposed component shelf 205 that is set up from the top surface of the web material between fins 105 by standoffs 206. Component shelf 205 provides mounting surface for other electronics modules and connectors that may be desired for any vacuum process.

Electrical pass through panel 207 includes at least one printed circuit board (PCB) adapted to accept specific standardized non-hermetic connectors like universal serial bus (USB), 10Base T, terminal block and IDC ribbon cable connectors. PCB design in this embodiment limits the number of through holes and vias that are on the part of the PCB that is subject to vacuum. In one embodiment, the electrical pass through (EPT) panel includes a copper layer just beneath the O-ring sealing surface on the vacuum side of the chamber (not visible here). The O-ring seal boundary is disposed just inside of the mounting bolt pattern.

In a preferred embodiment, connectors on the vacuum side are contained on the PCB within the boundary of the O-ring seal. On the atmospheric side of the chamber assembly, connectors may be placed outside of the O-ring seal boundary. In addition, each of the through holes on the atmospheric side of the assembly is filled with solder, and if necessary, sealed on the atmospheric side with a vacuum-compatible sealant.

The vacuum side of the PCB is held as flat and smooth in surface measurement as possible for contact to the O-ring sealing surface. With extension 202 added to base section 102, it is possible to have up to eight access panels (four per section). The panels are modular in nature and can be moved about and swapped for different types of panels. EPT panel 207 may be swapped out with another EPT panel of differing design. All of the hardware associated with a panel and access port is identical, regardless of the function of the panel. In a preferred embodiment, a single O-ring, 12 machine screws, and twelve washers are required to mount an access panel or cover plate. The chamber assembly without extension implements four access ports in its standard configuration. The plate material for each access port adds one O-ring to the mix. Plates are reasonably thick, up to one eight of an inch or so to ensure minimal deformation to the plate and the associated O-ring while the chamber is operated under vacuum pressure.

A user can create access port panels to suit their own needs. A user may, for example, choose to make the panels from an exotic material, or the user may braze fixtures to a panel, or other modifications may be made without departing from the spirit and scope of the present invention.

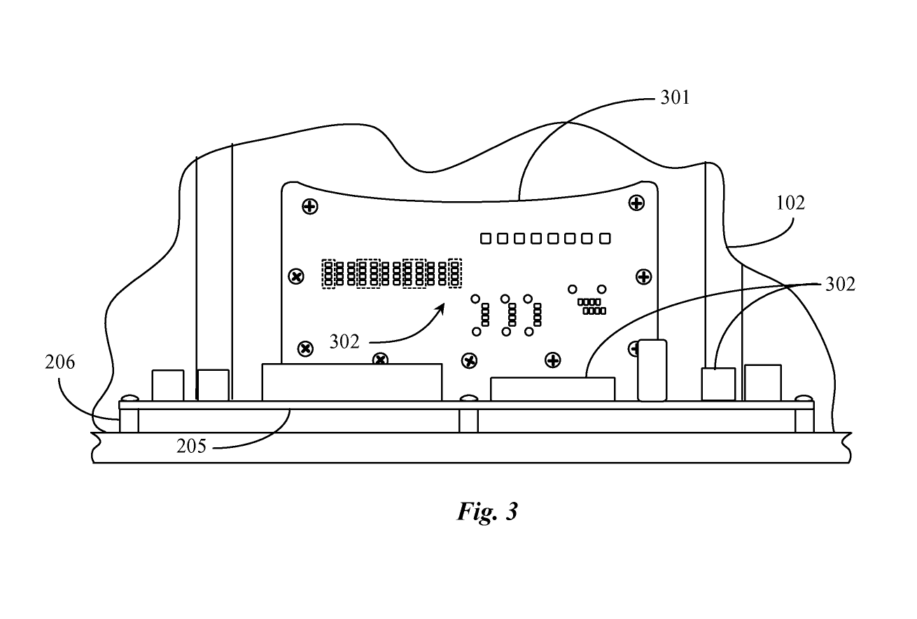

FIG. 3 is a partial view of a chamber with an electrical pass-through panel 301 and component shelf 205 installed according to an embodiment of the present invention. Panel 301 is illustrated in this example installed in the sidewall of base section 102, shown in partial view here. Panel 301 includes vias or through holes for standard pinhole connectors. Component shelf 205 is adapted to hold electric modules 303. EPT panel 301 includes the various and sundry connector pinhole patterns 302 for connecting the appropriate connector types to the panel.

A typical electrical pass-through panel supporting USB requires dedicated connectors on the vacuum side as well as on the atmospheric side of the chamber. Hermetic connectors can be extremely expensive, and do not offer the choices of pin types, pin numbers, connector schemes, etc. as do non-hermetic connectors. Associated traces are required to have impedance control. In an embodiment of the invention, panel 301 sealed against the base section wall, has only endpoint connectors on the vacuum side, and general-purpose connectors can be mounted to the atmospheric side for mating to any other panels. EPT panel 301 is connected to another panel, like component shelf 205, for example, by simple mating headers. Therefore, no cabling is required. The net result is that EPT panel can remain undisturbed while component shelf 205 or another panel (not illustrated) is removed, serviced, changed or tested. Component shelf 205 is a panel that includes other endpoint connectors, which can be arranged and/or customized by the end user.

In this example, the non-vacuum endpoint panel or component shelf can be removed, serviced and replaced without disturbing the vacuum process. Each EPT panel is implemented as a PCB populated with electronic and electrical components. The current combination includes pass through for one 10BaseT cable, three USB cables, eight general-purpose signals by a terminal block, and fifteen differential signals by IDC ribbon cable.

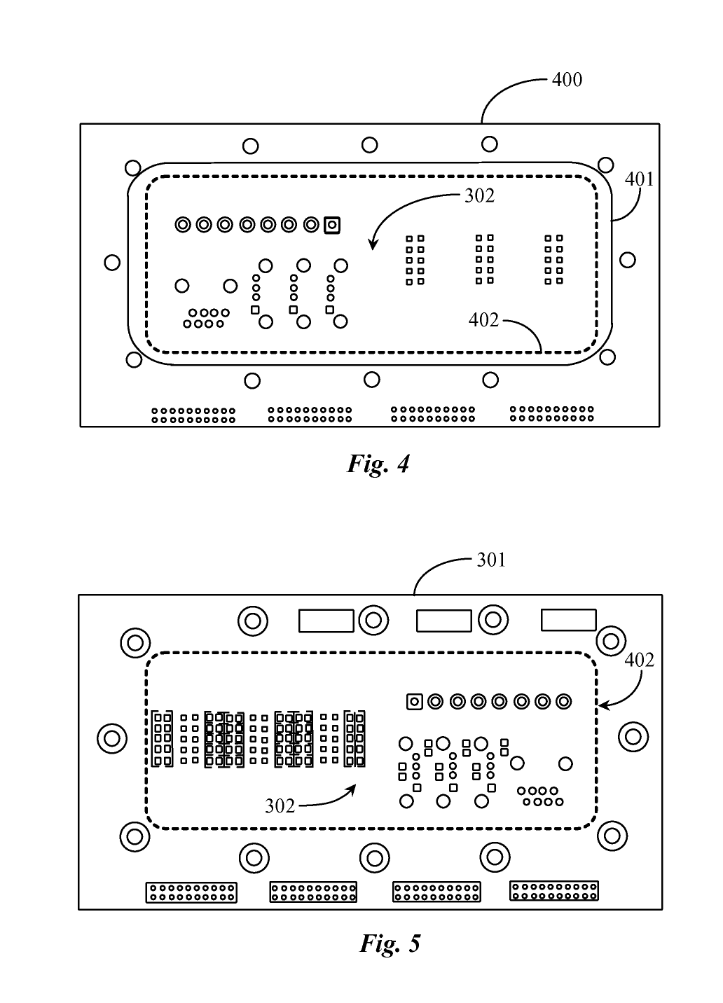

FIG. 4 is an elevation view of the vacuum side of an electrical pass-through panel 400 according to an embodiment of the present invention. EPT panel 400 is rectangular in profile and lacks the accurate top edge of panel 301. A flat and smooth layer of gold 401 deposited over copper provides a suitable surface for sealing to an O-ring. The O-ring is represented by a broken boundary 402. The metallic layer of copper coated with gold is deposited over the PCB materials and occupies an area just inside the hole pattern. Connector hole patterns 403 appear as they are viewed from the inside of the chamber assembly.

Vias (plated through holes) and electrical traces are not illustrated in this example but are assumed present where required. In a preferred embodiment traces and vias provide electrical communication paths between connectors mounted on both sides of the PCB EPT panel. The O-ring seats just inside of the gold area as shown by the broken boundary 402. The gold area includes no silkscreen or solder mask on it. It is also noted herein that no PCB traces cross the O-ring contact area at the edge of the gold layer. Connectors are mounted from this side and are soldered in place in all of the visible holes (vias) within the gold area 401.

FIG. 5 is an elevation view of the atmospheric side of the electrical pass-through panel 400 of FIG. 4. EPT 400 is viewed in this example from the outside of the vacuum chamber assembly. O-ring boundary 402 is represented by broken boundary for reference only. Electrical pinhole patterns 403 are illustrated as they appear from the atmospheric side of the chamber. Although not specifically illustrated, there is liberal use of white solder mask and black silkscreen, which is not compatible on the vacuum side. Moreover, PCB traces are abundant throughout the surface. It is possible because it is all outside of the chamber assembly and not influenced by the vacuum. On the outside surface, only surface-mount components can be attached within the area bounded by the O-ring seal (402). Through hole components may be attached outside of the O-ring boundary.

A important note to this approach is a careful PCB design, that limits the numbers of through holes or vias that are on the portion of the PCB that is exposed to chamber vacuum, and avoids any traces or other unevenness in the copper layer beneath the O-ring sealing surface. This is unique in that on the non-vacuum side of the PCB, connectors are outside of the region sealed by the O-ring. Additionally, each of these holes is filled with solder, and if necessary, sealed on the outside (i.e., non-vacuum side) with a vacuum-compatible sealant. The vacuum side of the PCB and especially the part that contacts the O-ring of the access port is designed to be as flat and smooth as possible, within conventional PCB manufacturing techniques. A minimal number of layers in the PCB is also recommended. With this approach, the only path for possible leakage into the vacuum chamber is through the PCB material itself.

It is noted herein that on the non-vacuum side of the chamber, only surface-mount components can be attached within the area enclosed by the O-ring seal. Through hole components may be attached outside of the O-ring seal area. With respect to the process described above, the atmospheric side of the electrical pass-through panel includes liberal use of vacuum-chamber-compatible (white) solder mask and black silkscreen, and the fact that PCB traces are present throughout this surface. On the atmospheric side, only surface-mount components can be attached to the PCB within the area enclosed by the O-ring seal. Through-hole components or connectors can be attached to the PCB outside of the O-ring area.

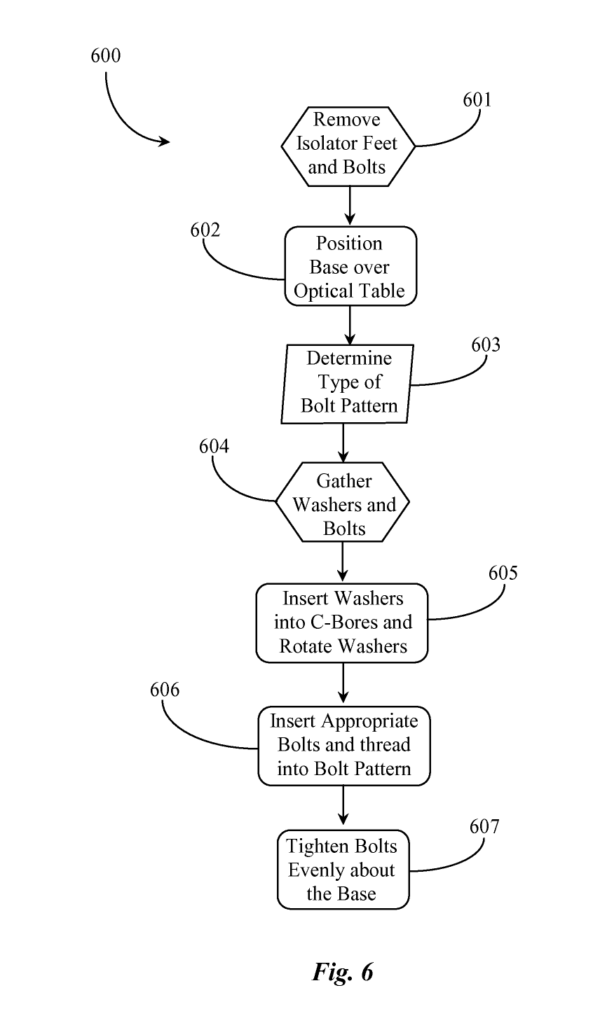

FIG. 6 is a process flow chart 600 illustrating steps for mounting a chamber assembly to an optical table according to an embodiment of the present invention. Flow chart 600 outlines a basic process that will vary slightly according to the type of bolt pattern encountered on an optical table.

At step 601, the user removes the isolator feet and bolts and washers from the mounting fins of the chamber assembly base section to be mounted to an optical table. At step 602 the user positions the base over the table and visually aligns the fin pattern over the bolt pattern on the optical table. At step 603 the user may determine which type of bolt pattern will be used, metric or inch. In one embodiment there may be both patterns on a single optical table.

At step 604, the user gathers the appropriate washers and bolts for the specific bolt pattern. In one aspect of the method, the washers may be used for both bolt patterns by providing an offset hole through each washer that is large enough in diameter to accepts both bolt diameters. Another relationship between the washer and counter bore is that the counter bore must be large enough to accept the bolt heads of either bolt type with the washer rotated in either direction.

At step 605, the user inserts the washers and bolts into the counter bores making sure that the washers are rotated to the correct position for the correct bolt pattern, metric or inch. In this case the offset hole in the washer may be visually aligned over the appropriate hole before the bolt is inserted into the counter bore. In one aspect the metric bolts are M6 bolts and the inch pattern bolts are one quarter-20 bolts.

At step 606 the user inserts the appropriate bolts into the counter bores and starts the bolts into the boltholes of the selected bolt pattern. At step 607, the user tightens the bolts about the base evenly. It will be apparent to one with skill in the art that the process steps of process flow 600 may be altered in order without departing from the spirit and scope of the present invention. For example, step 603 may be the first process step instead or the third process step without changing the process dynamics and end result.

It will be apparent to one with skill in the art that the desktop vacuum chamber assembly of the invention may be provided using some or all of the mentioned features and components without departing from the spirit and scope of the present invention. It will also be apparent to the skilled artisan that the embodiments described above are specific examples of a single broader invention that may have greater scope than any of the singular descriptions taught. There may be many alterations made in the descriptions without departing from the spirit and scope of the present invention.

What is claimed is:

1. An electrical pass-through panel for a vacuum chamber comprising:
a printed circuit board (PCB) having a substrate, at least one conductive and non-conductive material layer, the PCB sealed in mounting to the vacuum chamber with an O-ring seal seated in a groove provided about an opening through the wall of the vacuum chamber;
a plurality of vias provided through the PCB within the O-ring seal area, the vias corresponding directly to pin patterns for specified standard electrical connectors mountable on the vacuum side of the PCB;
a plurality of conductive traces defined on the non-vacuum side of the PCB, the traces in communication with the vias, the traces extending outside the O-ring seal area and culminating at a like number of vias arranged in like pin patterns for standard electrical connectors mountable on the non-vacuum side of the PCB outside of the area bounded by the O-ring seal;
wherein high speed data signals are passed through the vias and traces from the vacuum-side connectors plugged into the PCB within the O-ring seal area to the non-vacuum-side connectors plugged into the PCB outside of the O-ring seal area while the chamber is under vacuum.

2. The electrical pass-through panel of claim 1, wherein the standard connectors include but are not limited to universal serial bus (USB), 10baseT, insulation displacement connectors (IDC), and terminal blocks.

3. The electrical pass-through panel of claim 1, wherein the vias are electroplated.

4. The electrical pass-through panel of claim 1, wherein the conductive layer is a copper layer.

5. The electrical pass-through panel of claim 1, wherein the conductive traces are copper traces.

6. The electrical pass-through panel of claim 1, wherein the vias are sealed on the outside surface of the PCB with a vacuum compatible sealant.

7. The electrical pass-through panel of claim 1, wherein the vias are filled with solder.

8. The electrical pass-through panel of claim 1, serving as a modular assembly that can be dismounted and remounted at another opening in the vacuum chamber.

9. The electrical pass-through panel of claim 1, further including a horizontally disposed PCB panel connected thereto by headers, the horizontal panel supported by standoffs.

10. The electrical pass-through panel of claim 1, wherein the vacuum-side connectors are surface mounted and the non-vacuum side connectors are general-purpose connectors.

11. A method for establishing a communication path between standard connectors on opposite sides of a PCB mounted to a vacuum chamber with an O-ring seal comprising the steps:
(a) providing a plurality of vias through the PCB in the form of a connector pin pattern within the O-ring seal area to enable surface mounting of the type connector to the vacuum side of the PCB;
(b), providing a plurality of vias through the PCB in the form of a pin pattern compatible to the pin pattern of step (a) outside of the O-ring seal area to enable plug in of the type connector to the pin pattern on the non-vacuum side of the PCB; and
(c) on the non-vacuum side of the PCB, providing a conductive trace leading from each of the exposed vias of step (a) across the face of the PCB to each of the exposed vias of step (b).

12. The method of claim 11, wherein in step (a), the type connector is one of a universal serial bus (USB), 10baseT, insulation displacement connector (IDC), or a terminal block.

13. The method of claim 11, wherein in steps (a) and (b), the vias are electroplated and filled with solder.

14. The method of claim 11, wherein in step (b), the vias are sealed with a vacuum compatible sealant.

15. The method of claim 11, wherein in step (c), the conductive traces are copper traces.

16. The method of claim 11, wherein in step (c), the conductive traces are controlled with respect to impedance relative to the type connector subject to the communication path.
